(19) United States
(12) Patent Application Publication
(10) Pub. No.: US 2004/0231582 A1
(43) Pub. Date: Nov. 25, 2004

(54) Annealing method for halide crystal

(76) Inventors: Jonathan W. Foise, Mentor, OH (US); Thomas Andrew Campbell, University Heights, OH (US)

Correspondence Address: Renner, Otto, Boisselle & Sklar, 1621 Euclid Ave. -19th Floor, Cleveland, OH, 44115, US

(21) Appl. No.: 10/788,005

(22) Filed: Feb. 25, 2004

Related U.S. Application Data
(60) Provisional application No. 60/451,166, filed on Feb. 28, 2003.

(51) Int. Cl. C30B 1/00

(52) U.S. Cl. 117/3

(57) ABSTRACT

Improved outgassing techniques for decreasing oxygen and water concentrations in an annealing furnace, with the result being a significant reduction if not elimination of crystal defects. At the beginning of an annealing process, an airtight chamber of the annealing furnace is evacuated and filled with an inert gas not only one time but multiple times. During the anneal, inert gas, with or without a fluorinating agent, is flowed through the chamber during the heating and cooling steps while the oxygen and water concentrations in the flowing gas are each maintained below 5 ppm and more preferably below 1 ppm.

This application claims the benefit of U.S. Provisional Application No. 60/451,166, which is hereby incorporated herein by reference in its entirety.

The present invention relates to a method for preventing damage to halide crystals, more particularly to fluoride crystals, and still more particularly to single crystals of fluoride, such as calcium fluoride, during an annealing treatment that is applied to improve material quality and particularly to decrease stress birefringence and remove slip strain.

### BACKGROUND

The growth of halide crystals and particularly the growth of single crystals of fluoride, such as calcium fluoride (fluorite), have conventionally been conducted using a variety of methods such as the Bridgman process (i.e., crucible lowering method), a gradient freeze or slab furnace method, or Czochralski or Kyropoulos methods. A crystal grown by any one of these or other processes usually needs to be annealed to improve material quality and particularly to remove or at least reduce residual stress and strain. This is particularly true if the crystal is to be used in an optical system, such as a lens or window material, for various devices that utilize a laser in the ultraviolet wavelength range or the vacuum ultraviolet wavelength range, such as a stepper, CVD apparatus, or nuclear fusion apparatus.

The annealing process is carried out in an annealing furnace wherein the crystal can be heated and/or cooled in a controlled manner to improve material quality and particularly to remove dislocations which contribute to stress birefringence and slip strain. Usually, the crystal is placed in a container made of a material such as carbon that has a low reactivity at the annealing temperatures. The container and crystal are then enclosed in an airtight annealing furnace which may be evacuated of air and then filled with an inert gas such as argon. The inert gas may simply blanket the crystal and container, or the inert gas may be caused to flow over the crystal and container.

However, with conventional annealing methods, the surface of the crystal may become pitted or may have a haze formed thereon by foreign objects, impurities, moisture and oxygen components that become attached to or absorbed in the surface of the annealed crystal. These defects can render the crystal unsuitable for the aforesaid optical applications. In particular, the defects can result in absorptions in the transmission spectrum up to 1000 nm and particularly in the region of 140 to 220 nm, thereby rendering the crystal unsuitable for optical applications at 193 nm. The damage may extend up to about 25 mm into the crystal.

Fluorinating agents, such as CF₄ or polytetrafluoroethylene, have been used in an attempt to minimize the above-noted damage. However, as observed in U.S. Pat. No. 6,146,456, the surface of the crystal may still be etched due to the heat and the existence of a fluorination agent during the annealing process. The remedy has been to remove the damaged material, but this undesirably reduces yield.

### SUMMARY OF THE INVENTION

The inventors of the present invention have discovered that the above mentioned latent defects arising from the prior art annealing methods are the result of inadequate removal of oxygen and moisture from the annealing furnace. The present invention provides improved outgassing techniques for decreasing oxygen and water concentrations in the annealing furnace, with the result being a significant reduction if not elimination of the above noted defects.

According to one aspect of the invention, a method of annealing a fluoride crystal, particularly a single crystal of calcium fluoride, comprises the steps of:

(a) housing a fluoride crystal in an airtight chamber of an annealing furnace;

(b) thereafter evacuating the chamber;

(c) thereafter filling the chamber with an inert gas;

(d) heating the fluoride crystal to an annealing temperature lower than a melting point of the fluoride crystal; and

(e) thereafter gradually lowering the temperature of the fluoride crystal.

In a preferred embodiment, steps (b) and (c) are repeated at least one additional time and more preferably at least two additional times. Each time, the chamber preferably is evacuated to a vacuum level of 1 Torr or less, and the chamber is filled with an inert gas to a pressure of 1 Torr to 10 Atm., more preferably to a pressure of 0.5 Atm. to 5 Atm. and most preferably to a pressure of about 1 Atm. Most preferably the chamber is evacuated to a vacuum level of about 10 mTorr or less and most preferably to a vacuum level of about 1 mTorr or less.

According to another aspect of the invention, a method of annealing a fluoride crystal comprises the steps of: housing a fluoride crystal in an airtight chamber of an annealing furnace; thereafter evacuating the chamber; thereafter filling the chamber with an inert gas; thereafter heating the fluoride crystal to an annealing temperature lower than a melting point of the fluoride crystal; thereafter gradually lowering the temperature of the fluoride crystal; flowing an inert gas through the chamber during the heating and cooling steps; and maintaining the oxygen and water concentrations in the flowing gas below 5 ppm. In a preferred embodiment, a gas purifier is used to maintain the oxygen and water concentrations in the flowing gas below 1 ppm.

The foregoing and other features of the invention are hereinafter more fully described and particularly pointed out in the claims, the following description and the annexed drawings setting forth in detail certain illustrative embodiments of the invention, these being indicative, however, of but a few of the various ways in which the principles of the invention may be employed.

### BRIEF DESCRIPTION OF THE DRAWING

FIG. 1 is a graph showing the change in % transmission at 193 nm from before to after annealing (negative number indicate a decrease in transmission) as a function of the vacuum achieved during the evacuation.

### DETAILED DESCRIPTION

As above indicated, the present invention provides improved outgassing techniques for decreasing oxygen and water concentrations in an annealing furnace, with the result being a significant reduction if not elimination of the above noted defects. The principles of the invention may be applied to any halide crystal annealing process as will be evident to those skilled in the art, and particularly to the annealing of fluoride crystals, and still more particularly to single crystals of fluoride, such as calcium fluoride. The crystal can be grown using a conventional process, such as the Bridgman process (i.e., crucible lowering method), a gradient freeze or slab furnace method, or Czochralski or Kyropoulos methods. A crystal grown by this process usually needs to be annealed to improve material quality and particularly to remove or at least reduce residual stress and strain. This is particularly true if the crystal is to be used in an optical system, such as a lens or window material, for various devices that utilize a laser in the ultraviolet wavelength range or the vacuum ultraviolet wavelength range, such as a stepper, CVD apparatus, or nuclear fusion apparatus. The present invention can be applied to obtain single crystals of calcium fluoride suitable for use in optical devices operating at 193 nm or less.

The annealing process is carried out in an annealing furnace wherein crystal can be heated and/or cooled in a controlled manner to remove dislocations which contribute to stress birefringence and slip strain. The annealing furnace can be of any suitable type including an airtight chamber. The crystal can be placed in a container made of a material such as carbon that has a low reactivity at the annealing temperatures. Prior to doing so, foreign objects and impurities can be removed by ultrasonic cleaning, scrub cleaning or other cleaning treatment.

The container and crystal are then enclosed in the airtight chamber which may be evacuated of air and then filled with an inert gas such as argon. The inert gas can simply blanket the crystal and/or container, or more preferably the inert gas can be caused to flow over the crystal and/or container. Fluorinating agents, such as CF₄ or polytetrafluoroethylene, can be used to minimize the damage to the crystal during the annealing process. However, prior annealing methods still had been plagued by hazing of the crystal and/or other crystal defects, necessitating removal of a substantial amount of the crystal and a corresponding reduction in yield.

The inventors of the present invention have found that such defects arise from the reactivity of either oxygen or water being greater with the fluoride crystal than it is with the fluorinating agents particularly at the relatively low temperatures during warm-up and/or cooling down of the crystal, such that damage to the crystal occurs during these periods.

In accordance with the invention, damage from these defects can be decreased if not eliminated by further process steps that further reduce the concentration of oxygen and/or water in the annealing furnace, particularly at the beginning and end of the annealing process. At the beginning of the annealing process, the airtight chamber of the annealing furnace is evacuated and filled with an inert gas not only one time but multiple times. In a preferred embodiment, the chamber is evacuated each time to a vacuum level of 1 Torr or less. Most preferably the chamber is evacuated to a vacuum level of about 10 mTorr or less and most preferably to a vacuum level of about 1 mTorr or less. After each evacuation, the chamber is filled with an inert gas preferably to a pressure of 1 Torr to 10 Atm., more preferably to a pressure of 0.5 Atm. to 5 Atm. and most preferably to a pressure of about 1 Atm. The inert gas can be nitrogen for example and can include one or more fluorinating agents such as CF₄ or polytetrafluoroethylene.

After the annealing chamber has been outgassed in this manner, the crystal may be subjected to a desired annealing procedure during which the crystal is heated to an annealing temperature lower than a melting point of the fluoride crystal unless the fluoride crystal is already at the annealing temperature. As used herein, the annealing temperature is an elevated temperature to which the crystal is heated to effect annealing of the crystal and from which the crystal is gradually lowered. Depending on the annealing procedure, the crystal may be subjected to one or more heat-ups and cool-down cycles. Annealing procedures are well known in the art and need not be described in greater detail as the principles of the present invention are generally applicable to such known annealing procedures.

According to another aspect of the invention, the inert gas, with or without a fluorinating agent, is flowed through the chamber during the heating and cooling steps while the oxygen and water concentrations in the flowing gas are each maintained below 5 ppm by volume and more preferably below 1 ppm. In a preferred embodiment, a gas purifier is used to maintain the oxygen and water concentrations in the flowing gas below 1 ppm.

The foregoing process steps that further reduce the concentration of oxygen and/or water in the annealing furnace contribute to the production of a fluoride crystal, and particularly a single crystal of calcium fluoride, of extremely high quality with high transmittance and essentially no haze or scattering. More particularly, there can be obtained crystals having significantly reduced absorption in the region of 140 to 220 nm and significantly reduced scattering. Thus, there is provided a fluoride crystal suitable for use, for example, in optical applications at 248 nm, 193 nm and 157 nm wavelengths.

Generally, a warm purge can be effected as follows. A chamber of an annealing furnace is evacuated and filled with an inert gas as described. After the last evacuation the furnace is heated, under vacuum, up to an elevated temperature less than or equal to the annealing temperature. The preferred evacuation temperature is from 50° C. to 900° C., and the more preferred is from 300° C. to 700° C. The chamber is held under vacuum at this elevated temperature till the vacuum level and leak rate are constant. The chamber is then filled with the inert gas and the furnace is heated to the annealing temperature. CF₄ (gas) can be added to the inert gas as a getter, although other getters are also contemplated such as NH₄F, NH₄HF₂, PbF₂, SnF₂, ZnF₂, Ti metal, Cu metal, and combinations thereof.

### EXAMPLE 1

A calcium fluoride crystal is loaded into a graphite container which is placed into an annealing furnace. The furnace is evacuated and backfilled with argon three times. The best vacuum achieved is on the third evacuation and is 387 mtorr. After the third backfilling, the crystal is heated to an annealing temperature of 950° C. under a flowing gas mixture of 4% CF₄/96% Argon, held at the annealing temperature, then cooled to room temperature. The crystal, with an optical path length of 30 mm, has a change in percent transmission, from before to after the annealing, of 28% at 193 nm and 48% at 157 nm. After annealing the crystal showed a decrease in transmission after an exposure to a 193 nm laser of 4.5% at 380 nm.

### EXAMPLE 2

A calcium fluoride crystal is loaded into a graphite container which is placed into an annealing furnace. The furnace is evacuated and backfilled with argon five times. The argon used is passed through a purifier (model # SS-35KF-I-4R supplied by Aeronex)) that is designed to achieve an oxygen and water concentration of 1 ppm or less. The best vacuum achieved is on the fifth evacuation and is 21 millitorr. After the fifth backfilling, the crystal is heated to an annealing temperature of 950° C. under a flowing gas mixture of 4% CF₄/96% Argon, held at the annealing temperature, then cooled to room temperature. The crystal, with an optical path length of 30 mm, has a change in percent transmission, from before to after the annealing, of 3% at 193 nm and 8% at 157 nm.

### EXAMPLE 3

A calcium fluoride crystal is loaded into a graphite container which is placed into an annealing furnace. The furnace is evacuated and backfilled with argon five times. The argon used is passed through a purifier (model described above) that is designed to achieve an oxygen and water concentration of 1 ppm or less. The best vacuum achieved is on the fifth evacuation and is 0.7 millitorr. After the fifth evacuation, the furnace is kept under vacuum and heated to 400° C. It is held at this temperature in vacuum for 6 days. After that, the furnace is backfilled with argon and the crystal is heated to an annealing temperature of 950° C. under a flowing gas mixture of 4% CF₄/96% Argon, held at the annealing temperature, then cooled to room temperature. The crystal, with an optical path length of 30 mm, has a change in percent transmission, from before to after the annealing, of 0.3% at 193 nm and 3.9% at 157 nm. After annealing the crystal showed a decrease in transmission after an exposure to a 193 nm laser of 0.8% at 380 nm.

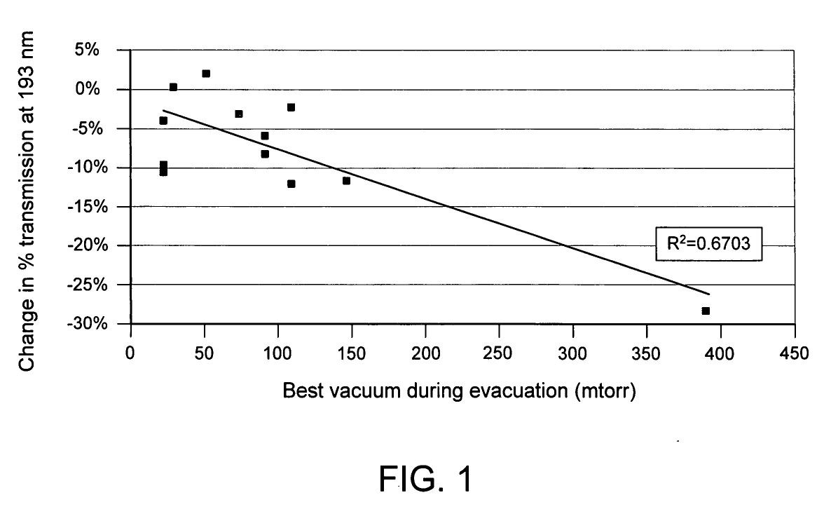

FIG. 1 shows the change in % transmission at 193 nm from before to after annealing (negative number indicate a decrease in transmission) as a function of the vacuum achieved during the evacuation. A linear regression with better than 99% confidence is shown.

The herein described annealing procedures of the present invention can have applicability to the manufacture of halide crystals and particularly halide single crystals, more particularly to fluoride crystals and particularly fluoride single crystals, and still more particularly to single crystals of fluoride, such as calcium fluoride. Of course, the herein described annealing procedures can have still wider application, such as for annealing sodium iodide.

Although the invention has been shown and described with respect to a certain preferred embodiment or embodiments, it is obvious that equivalent alterations and modifications will occur to others skilled in the art upon the reading and understanding of this specification and the annexed drawing. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

What is claimed is:

1. A method of annealing a crystal comprising the steps of:
(a) housing a crystal in an airtight chamber of an annealing furnace;
(b) thereafter evacuating the chamber;
(c) thereafter filling the chamber with an inert gas;
(d) repeating steps (b) and (c) at least one additional time.
(e) heating the crystal to an annealing temperature lower than a melting point of the crystal; and
(f) thereafter gradually lowering the temperature of the crystal.

2. The method of claim 1, wherein the chamber is held under vacuum during an initial heating of the crystal to a temperature less than the annealing temperature, and then introducing an inert gas into the chamber and thereafter heating the crystal to the annealing temperature.

3. The method of claim 1, wherein step (d) includes repeating steps (b) and (c) at least two additional times.

4. The method of claim 1, comprising the step of:
(g) flowing an inert gas through the chamber during at least one of step (e) and step (f).

5. The method of claim 4, comprising the step of:
(h) maintaining the oxygen and water concentrations in the flowing gas of step (g) below 5 ppm.

6. The method of claim 4, comprising the step of:
(h) maintaining the oxygen and water concentrations in the flowing gas of step (g) below 1 ppm.

7. The method of claim 6, wherein step (h) includes using a gas purifier to remove oxygen and water from the flowing gas.

8. The method of claim 5, wherein step (h) includes using a gas purifier to remove oxygen and water from the flowing gas.

9. The method of claim 5, wherein step (b) includes evacuating the chamber to a vacuum level of 1 Torr or less.

10. The method of claim 4, wherein step (b) includes evacuating the chamber to a vacuum level of 1 Torr or less.

11. The method of claim 1, wherein step (b) includes evacuating the chamber to a vacuum level of 1 Torr or less.

12. The method of claim 1, wherein step (b) includes evacuating the chamber to a vacuum level of 50 mTorr or less.

13. The method of claim 10, wherein step (c) includes filling the chamber with an inert gas to a pressure of about 1 Torr to about 10 Atm.

14. The method of claim 1, wherein step (c) includes filling the chamber with an inert gas to a pressure of about 0.5 Atm. to about 5 Atm.

15. The method of claim 1, wherein step (c) includes filling the chamber with an inert gas to about 1 Atm.

16. The method of claim 1, wherein the crystal is a halide crystal.

17. The method of claim 1, wherein the crystal is a fluoride crystal.

18. The method of claim 17, wherein the fluoride crystal is a single crystal of calcium fluoride.

19. The method of claim 1, including the step of adding a getter to the inert gas, and the getter is selected from a group consisting of NH4F, NH4HF2, PbF2, SnF2, ZnF2, Ti metal, Cu metal, and combinations thereof.

20. A fluoride crystal annealed in accordance with the method of claim 1.

21. A fluoride crystal annealed in accordance with the method of claim 4.

22. A fluoride crystal annealed in accordance with the method of claim 8.

23. A fluoride crystal annealed in accordance with the method of claim 12.

24. A single crystal of calcium fluoride annealed in accordance with the method of claim 13.

25. A halide crystal annealed in accordance with the method of claim 1, and having no greater than 0.5% loss in transmission at 157 nm.

26. A method of annealing a fluoride crystal comprising the steps of: housing a fluoride crystal in an airtight chamber of an annealing furnace; thereafter evacuating the chamber; thereafter filling the chamber with an inert gas; heating the fluoride crystal to an annealing temperature lower than a melting point of the fluoride crystal; thereafter gradually lowering the temperature of the fluoride crystal; flowing an inert gas through the chamber during the at least one of the heating and cooling steps; and maintaining the oxygen and water concentrations in the flowing gas below 5 ppm.

27. The method of claim 26, wherein a gas purifier is used to maintain the oxygen and water concentrations in the flowing gas below 1 ppm.
